(19) United States
(12) Patent Application Publication
(10) Pub. No.: US 2004/0177982 A1
(43) Pub. Date: Sep. 16, 2004

(54) Image display having electromagnetic shield and method for producing same

(75) Inventor: Takeshi Shibata, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/801,577

(22) Filed: Mar. 17, 2004

(30) Foreign Application Priority Data
Mar. 15, 2003 (JP) 2003-074493

(51) Int. Cl. H05K 9/00

(52) U.S. Cl. 174/35 MS

(57) ABSTRACT

An image display has an electromagnetic shield comprising a conductive material with an irregular network structure. The image display is obtained by forming a thin film on a substrate; generating microcracks in a network manner in the thin film; and forming a layer of the conductive material in the microcracks. The electromagnetic shield has excellent electromagnetic-shielding properties and high light transmittance.

### FIELD OF THE INVENTION

The present invention relates to an image display having an electromagnetic shield with excellent electromagnetic-shielding properties and high light transmittance, and a method for producing such an image display.

### BACKGROUND OF THE INVENTION

With recent rapid development of various electronics devices, attention has been paid to damage to human body caused by electromagnetic waves radiated from the electronics devices, and thus various electromagnetic shields have been developed as measures of suppressing electromagnetic wave radiation. The electromagnetic waves from the electronics devices are generally shielded by using metal housings or by attaching metal plates to the housings. However, to shield electromagnetic waves radiated from display plates of CRTs, PDPs (plasma display panels), etc., the electromagnetic shields should be excellent not only in electromagnetic-shielding properties but also in light transmittance, whereby the metal plates cannot be used as the electromagnetic shields. Thus, various technologies for achieving both of the electromagnetic-shielding properties and the light transmittance have been proposed.

The electromagnetic shields having both electromagnetic-shielding properties and light transmittance are generally classified into two types, a uniform, transparent, conductive film type and a network conductor type. Proposed as the electromagnetic shields of the uniform, transparent, conductive film type are thin, conductive films formed by depositing a metal or a metal oxide onto a transparent substrate, which are disclosed in JP 1-278800 A and JP 5-323101 A. This depositing method is, however, disadvantageous in terms of cost and productivity, because it needs a vacuum treatment and a high-temperature treatment. If the deposited film were thin to achieve sufficient light transmittance, it would have a reduced surface resistance, resulting in the lowered attenuation of electromagnetic waves. Thus, this method cannot satisfy both requirements of electromagnetic-shielding properties and light transmittance.

Transparent conductive paints comprising conductive oxide particles or colloids are proposed in JP 6-344489 A, JP 7-268251 A, etc. However, transparent conductive films formed from the paints have low conductivity.

The network conductor-type electromagnetic shields having network patterns are made of metals capable of shielding electromagnetic waves. The network pattern should be uniform and fine to achieve the above requirement. Electromagnetic shielding fibers containing high-conductivity metal filaments and electromagnetic shields having high-conductivity metal fibers such as stainless steel and tungsten embedded therein are disclosed in JP 3-35284 A, JP 5-269912 A and JP 5-327274 A. Despite the fact that these electromagnetic shields have as large electromagnetic shielding as 40 to 50 dB at 1 GHz, however, the conductive fibers should have as large diameters as at least 35 μm for regular arrangement to prevent electromagnetic waves from leaking. Thus, these electromagnetic shields are disadvantageous in that the conductive fibers are visible, or that resins, etc. in the vicinity of the embedded fibers are deformed, resulting in image distortion.

Methods of screen-printing conductive compositions containing conductive particles such as metal particles on substrates are described in JP 62-57297 A and JP 2-52499 A. However, the printing methods are unsuitable for achieving excellent visibility, because of printing accuracy limited to approximately 100 microns of line width.

Methods of forming openings in metal sheets in a network pattern by photolithography are known by JP 5-283889 A and JP 2001-168574 A. Since the photolithography methods are costly because of many steps, JP 11-170420 A discloses a method comprising printing an electroless plating catalyst ink in a predetermined pattern on a transparent substrate and electroless-plating a conductive metal only on the ink. Conductive network shields control electromagnetic-shielding properties and light transmittance by adjusting line width and intervals by patterning. However, printed network patterns cannot have sufficiently fine lines, failing to provide satisfactory light transmittance and visibility. Though photolithography can produce relatively small line width, production cost dictates that line width be at least several tens of microns in large-area electromagnetic shields.

### OBJECTS OF THE INVENTION

Accordingly, an object of the present invention is to provide an image display having an electromagnetic shield with excellent electromagnetic-shielding properties and light transmittance.

Another object of the present invention is to provide a method for producing such an electromagnetic shield.

### SUMMARY OF THE INVENTION

As a result of intense research in view of the above objects, the inventor has found that an electromagnetic shield of a conductive material with an irregular network structure excellent in electromagnetic-shielding properties and light transmittance for image displays can be provided by forming a thin film on a transparent substrate, generating microcracks in a network manner in the thin film, and filling the microcracks with a conductive material. The present invention has been accomplished by this finding.

Thus, the image display of the present invention has an electromagnetic shield comprising a conductive material with an irregular network structure.

In the electromagnetic shield having a network structure, lines constituting the network structure are preferably as thin as 10 nm to 10 μm.

The method for producing an image display having an electromagnetic shield according to a first embodiment of the present invention comprises the steps of forming a thin film on a substrate; generating microcracks in a network manner in the thin film; and filling the microcracks with a conductive material to form the electromagnetic shield.

The method for producing an image display having an electromagnetic shield according to a second embodiment of the present invention comprises the steps of forming an underlayer on a substrate; forming a thin film on the underlayer; generating microcracks in a network manner in the thin film; activating portions of the underlayer exposed to the microcracks; removing the thin film; and depositing or bonding a conductive material only onto the activated portions of the underlayer to form the electromagnetic shield.

In the first and second methods, it is preferred that the thin film is (1) a sol-gel film obtained by applying a sol-gel liquid, (2) a fine-particle film obtained by applying a liquid containing fine particles, or (3) a vapor deposition film obtained by depositing a vaporized thin-film-forming material, the microcracks being generated by drying the sol-gel film or the fine-particle film or by accumulating stress in the vapor deposition film during its growth.

In the first and second methods, it is preferred that the thin film is formed after forming an underlayer by plating on the substrate, and that the conductive material layer is formed by plating on (1) portions of the plated underlayer exposed in the microcracks, or (2) the activated portions of the plated underlayer. More preferably, the plating is electroless plating, and the plated underlayer comprises a plating catalyst or its precursor.

In the first and second methods, it is preferred that the thin film is formed after forming an underlayer having bondability to the conductive material or acquiring bondability to the conductive material by activation on the substrate, and that conductive material particles are bonded to (1) portions of the bondable underlayer exposed to the microcracks, or (2) the activated portions of the bondable underlayer. The bondable underlayer preferably has a functional group bondable to the conductive material or a functional group acquiring bondability to the conductive material by activation.

### BRIEF DESCRIPTION OF THE DRAWINGS

FIG. 1 is a view showing an example of the production of an electromagnetic-shielding layer for the image display of the present invention; and

FIG. 2 is a view showing another example of the production of an electromagnetic-shielding layer for the image display of the present invention.

### DETAILED DESCRIPTION OF THE PREFERRED EMBODIMENTS

### [1] Electromagnetic-Shielding Layer

The image display of the present invention has an electromagnetic shield comprising an electromagnetic-shielding, conductive material layer having an irregular network structure. The “irregular network structure” described here may be exemplified by cracks generated in thin films, rice paddy, etc., when shrinking occurs in a surface direction. The electromagnetic-shielding conductive material constitutes a two-dimensional, continuous network. Thin lines constituting the electromagnetic-shielding network layer are preferably as thin as 10 nm to 10 μm. The thin lines are more preferably as thin as 10 nm to 5 μm, particularly 10 nm to 1 μm. When the line width is more than 10 μm, the light transmittance of the electromagnetic shield is too low. When the line width is less than 10 nm, however, it is practically difficult to form the electromagnetic-shielding layer.

The conductive material for the electromagnetic-shielding layer is not particularly restricted and may be a metal, a metal oxide, a conjugated polymer, or a composite thereof. In a case where a relatively high conductivity is needed, the conductive material preferably comprises a metal oxide such as ITO, or at least one metal selected from the group consisting of copper, aluminum, nickel, iron, gold, silver, stainless steel, tungsten, chromium and titanium. The conductive material may be a material for a transparent conductive layer that will be hereinafter described.

When a conductive metal is used in a display, a blackening layer is preferably formed on the electromagnetic-shielding layer to reduce the contrast due to metallic luster. The material for the blackening layer is not particularly restricted. For example, in the case of using copper as the conductive material, the blackening layer may be a black metal layer formed by a wet chemical treatment, in which the copper surface of the electromagnetic-shielding layer is treated with an aqueous solution of sodium chlorite, sodium hydroxide, trisodium phosphate, etc.

The surface resistivity of the electromagnetic-shielding layer is preferably 1000 Ω/square or less to achieve the requirement of TCO (The Swedish Confederation of Professional Employees) guideline. The light transmittance of the electromagnetic-shielding layer is preferably 50% or more. The substrate for the electromagnetic-shielding layer is not limited in terms of transparency, as long as image is visible in the display even in the dark. The visible light transmittance of the substrate with the electromagnetic-shielding layer is preferably 50% or more, more preferably 60% or more, particularly 70% or more.

There are no restrictions in the material of the substrate (support), on which the electromagnetic-shielding layer is formed. The substrate preferably has high transparency and excellent barrier property. Specific examples of such substrates include glass plates and transparent plastic films. The transparent plastic film preferably contains fine inorganic filler particles. The substrate such as a glass plate and a transparent plastic film is preferably coated with a high-transparency, inorganic oxide such as silicon oxide and silicon nitride.

The shape, structure, size, etc. of the substrate may be selected depending on its use. The substrate is generally in a plate shape, and the plate-shaped substrate preferably has a thickness of 5 μm to 5 mm. The substrate may have a single-layer structure or a multi-layer structure. Further, the substrate is preferably transparent and colorless, though it may be transparent and colored.

### [2] Production of Electromagnetic-Shielding Layer on Substrate

The electromagnetic-shielding layer can be produced on a substrate by (a) a direct method comprising the steps of forming a thin film on the substrate; forming microcracks in a network manner in the thin film; and filling the microcracks with a conductive material, or (b) an indirect method comprising the steps of forming an underlayer on the substrate; forming a thin film on the underlayer; forming microcracks in a network manner in the thin film; subjecting the portions of the underlayer exposed in the microcracks to an activation treatment; removing the thin film; and depositing a conductive material to the activated portions of the underlayer. The production of the electromagnetic-shielding layer on the substrate by the direct or indirect method is described below.

(1) Formation of Thin Film

In the production of the electromagnetic-shielding layer on the substrate, the thin film is not particularly limited with respect to materials and forming methods, as long as it can form microcracks on the substrate.

It is often observed in the nature that when mud (soil dispersed in water) in rice paddy, etc. is dried, for instance, it shrinks in a surface direction, resulting in cracks in a peculiar pattern. In the case of artifacts, concrete is often cracked with time, and decorative crackles are formed on a pottery with selected glaze. Utilizing these cracking phenomena, a microcrackable thin film can be obtained from industrially available materials with their compositions properly adjusted. Materials for the substrate may be selected from glass, polymers, metals, metal oxides, semiconductors, etc. depending on its use. The substrate preferably has a smooth surface. The thin film shrinks to generate microcracks mainly by drying, and by difference in a heat expansion coefficient between the thin film and the substrate. The shrinkage of the thin film changes depending on drying conditions, adhesion to the substrate, etc. Thus, the thin film material is selected, taking into account the materials and surface conditions of the substrate, the conditions for forming microcracks, etc. A sol-gel film or a fine-particle film is preferably formed as the thin film on the above substrate.

The thin film may be formed by usual methods. When the thin film is formed by a sol-gel method or a method of applying fine particles, for instance, wet methods such as a spin coating method, a gravure coating method, a dip-coating method, a casting method, a die coating method, a roll coating method, a bar coating method, an extrusion coating method, and an ink-jet coating method are usable. Further, when the thin film is formed by a vapor growth method, a DC sputtering method, a high-frequency sputtering method, a vacuum deposition method, an ion-plating method, etc. are usable.

(1-1) Sol-Gel Method

The formation of a sol-gel film as the thin film is illustrated below. The sol-gel film is defined as a thin film formed by turning a sol containing fine particles to a gel containing a solvent between the fine particles. The solvent between fine particles is volatilized so that the thin film shrinks in a surface direction to generate microcracks. The sol-gel film may comprise any organic or inorganic material that can form such a film. The sol-gel films and their materials are described in many books such as Sumio Sakka, Science of Sol-Gel Method, issued by Agune Shofusha (1988). The sol-gel film can be relatively easily formed by using a sol-gel reaction, wherein a metal alkoxide is hydrolyzed and condensed to form a metal oxide. The sol-gel film may be obtained by hydrolyzing the metal alkoxide in the presence of water and alcohol with an acid or base catalyst, applying the resultant solution to a substrate and drying the resultant film.

The metal alkoxide is preferably hydrolyzed and/or polycondensed in the solution or the applied film to obtain a dense thin film. A resin may be used in the hydrolysis and/or the polycondensation to obtain a thin film composed of an organic-inorganic hybrid material.

The metal alkoxides may be alkoxysilanes, other metal alkoxides than the alkoxysilanes, or their combinations. The other metal alkoxides than the alkoxysilanes are preferably selected from the group consisting of zirconium alkoxides, titanium alkoxides, and aluminum alkoxides.

The alkoxysilane is preferably represented by the following general formula (I):

Si(OR₁)ₓ(R₂)₄₋ₓ (I),

wherein R₁ is an alkyl group having 1 to 5 carbon atoms or an acyl group having 1 to 4 carbon atoms, R₂ is an organic group having 1 to 10 carbon atoms, and x is an integer of 2 to 4.

Preferred examples of R₁ include a methyl group, an ethyl group, an n-propyl group, an i-propyl group, an n-butyl group, a sec-butyl group, a tert-butyl group, an acetyl group, etc.

Preferred examples of R₂ include unsubstituted hydrocarbon groups such as a methyl group, an ethyl group, a n-propyl group, an i-propyl group, a n-butyl group, a tert-butyl group, a n-hexyl group, a cyclohexyl group, a n-octyl group, a tert-octyl group, a n-decyl group, a phenyl group, a vinyl group, and an allyl group; and substituted hydrocarbon groups such as a γ-chloropropyl group, a CF₃CH₂— group, a CF₃CH₂CH₂— group, a C₂F₅CH₂CH₂— group, a C₃F₇CH₂CH₂CH₂— group, a CF₃OCH₂CH₂CH₂— group, a C₂F₅OCH₂CH₂CH₂— group, a C₃F₇OCH₂CH₂CH₂— group, a (CF₃)₂CHOCH₂CH₂CH₂— group, a C₄F₉CH₂OCH₂CH₂CH₂— group, a 3-(perfluorocyclohexyloxy)propyl group, an H(CF₂)₄CH₂OCH₂CH₂CH₂— group, an H(CF₂)₄CH₂CH₂CH₂— group, a γ-glycidoxypropyl group, a γ-mercaptopropyl group, a 3,4-epoxycyclohexylethyl group, and a γ-methacryloyloxypropyl group.

Specific examples of the alkoxysilanes with x of 4 include tetramethoxysilane, tetraethoxysilane, tetra-n-propoxysilane, tetra-i-propoxysilane, tetra-n-butoxysilane, tetra-acetoxysilane, etc.

Specific examples of the alkoxysilanes with x of 3 include methyltrimethoxysilane, methyltriethoxysilane, ethyltrimethoxysilane, ethyltriethoxysilane, n-propyltrimethoxysilane, n-propyltriethoxysilane, i-propyltrimethoxysilane, i-propyltriethoxysilane, γ-chloropropyltrimethoxysilane, γ-chloropropyltriethoxysilane, γ-glycidoxypropyltrimethoxysilane, γ-glycidoxypropyltriethoxysilane, γ-methacryloyloxypropyltrimethoxysilane, γ-mercaptopropyltriethoxysilane, phenyltrimethoxysilane, vinyltriethoxysilane, 3,4-epoxycyclohexylethyltrimethoxysilane, 3,4-epoxycyclohexylethyltriethoxysilane, CF₃CH₂CH₂Si(OCH₃)₃, C₂F₅CH₂CH₂Si(OCH₃)₃, C₂F₅OCH₂CH₂CH₂Si(OCH₃)₃, C₃F₇OCH₂CH₂CH₂Si(OC₂H₅)₃, (CF₃)₂CHOCH₂CH₂CH₂Si(OCH₃)₃, C₄F₉CH₂OCH₂CH₂CH₂Si(OCH₃)₃, H(CF₂)₄CH₂OCH₂CH₂CH₂Si(OCH₃)₃, 3-(perfluorocyclohexyloxy)propyltrimethoxysilane, etc.

Specific examples of the alkoxysilanes with x of 2 include dimethyldimethoxysilane, dimethyldiethoxysilane, methylphenyldimethoxysilane, diethyldimethoxysilane, diethyldiethoxysilane, di-n-propyldimethoxysilane, di-n-propyldiethoxysilane, di-i-propyldimethoxysilane, di-i-propyldiethoxysilane, diphenyldimethoxysilane, divinyldiethoxysilane, (CF₃CH₂CH₂)₂Si(OCH₃)₂, (C₃F₇OCH₂CH₂CH₂)₂Si(OCH₃)₂, [H(CF₂)₆CH₂OCH₂CH₂CH₂]₂Si(OCH₃)₂, (C₂F₅CH₂CH₂)₂Si(OCH₃)₂, etc.

The resins (polymers) used for the sol-gel reaction preferably have hydrogen bond-forming groups, and preferred examples of such resins include hydroxyl group-containing polymers and derivatives thereof (e.g. polyvinyl alcohol, polyvinyl acetal, ethylene-vinyl alcohol copolymers, phenol resins, methylolmelamine, derivatives thereof, etc.); carboxyl group-containing polymers and derivatives thereof (e.g. poly(meth)acrylic acid, homopolymers and copolymers containing repeating units of polymerizable unsaturated acids such as maleic anhydride and itaconic acid, their esterified products containing repeating units of vinyl esters such as vinyl acetate, (meth)acrylates such as methyl methacrylate, etc.); ether bond-containing polymers (e.g. polyalkylene oxides, polyoxyalkylene glycols, polyvinyl ethers, silicone resins, etc.); amide bond-containing polymers (e.g. N-acylated products of polyoxazolines and polyalkylene imines having a >N(COR)— bond, in which R represents a hydrogen atom, a substituted or unsubstituted alkyl group, or a substituted or unsubstituted aryl group, etc.); polyvinylpyrrolidones and derivatives thereof having a >NC(O)— bond; polyurethanes; and urea bond-containing polymers.

The resins may be silyl-containing polymers. The silyl-containing polymers may have at least one silyl group having a silicon atom connected to a hydrolyzable group and/or a hydroxyl group per one molecule at end or in side chains, and preferably have plural silyl groups.

The amount of the resin added in the sol-gel reaction is preferably 1 to 100 parts by weight per 100 parts by weight of the metal alkoxide, such as alkoxysilane, or a mixture of alkoxysilane and other metal alkoxide when the other metal alkoxide is contained.

A catalyst is preferably used in the sol-gel reaction, in which the metal alkoxide is hydrolyzed and/or polycondensed in a solvent containing water and an organic solvent. The catalyst for the hydrolysis is generally an acid, which may be inorganic or organic. Examples of the inorganic acids include hydrochloric acid, hydrogen bromide, hydrogen iodide, sulfuric acid, sulfurous acid, nitric acid, nitrous acid, phosphoric acid and phosphorous acid. Examples of the organic acids include carboxylic acids such as formic acid, acetic acid, propionic acid, butyric acid, succinic acid, cyclohexane carboxylic acid, octanoic acid, maleic acid, 2-chloropropionic acid, cyanoacetic acid, trifluoroacetic acid, perfluoroctanoic acid, benzoic acid, pentafluorobenzoic acid, and phthalic acid; sulfonic acids such as methanesulfonic acid, ethanesulfonic acid, trifluoromethanesulfonic acid, p-toluenesulfonic acid, and pentafluorobenzene sulfonic acid; phosphoric or phosphonic acids such as dimethyl phosphate and phenyl phosphonate; Lewis acids such as boron trifluoride etherate, scandium triflate, alkyltitanic acids, and aluminum hydroxide; and heteropolyacids such as phosphomolybdic acid and phosphotungstic acid.

The amount of the acid is preferably 0.0001 to 0.05 mol, more preferably 0.001 to 0.01 mol, per 1 mol of the metal alkoxide such as alkoxysilane (the total of alkoxysilane and other metal alkoxide, when the other metal alkoxide is contained).

An inorganic base, or an organic base such as an amine may be added after the hydrolysis, to adjust the pH of the solution to around 7 to accelerate the polycondensation. The inorganic base may be sodium hydroxide, potassium hydroxide, calcium hydroxide, magnesium hydroxide, aluminum hydroxide, or ammonia, etc. Examples of the organic base include amines such as ethylenediamine, diethylenetriamine, triethylenetetramine, tetraethylenepentamine, triethylamine, dibutylamine, N,N-dimethylbenzylamine, tetramethylethylenediamine, piperidine, piperazine, morpholine, ethanolamine, diazabicycloundecenes, quinuclidine, aniline, and pyridine; phosphines such as triphenylphosphine and trimethylphosphine; etc.

The acid catalyst may be used with another sol-gel catalyst such as a metal chelate compound and an organic metal compound. Though not particularly restrictive, the metal chelate compound preferably contains a central metal with a ligand, which may be an alcohol represented by the following general formula (II):

R₃OH (II),

wherein R₃ is an alkyl group having 1 to 6 carbon atoms, or a diketone represented by the following general formula (III):

R₄COCH₂COR₅ (III),

wherein R₄ is an alkyl group having 1 to 6 carbon atoms, and R₅ is an alkyl group having 1 to 5 carbon atoms or an alkoxy group having 1 to 16 carbon atoms.

Two or more such metal chelate compounds may be combined. The metal chelate compound preferably has a central metal of Al, Ti or Zr. The metal chelate compound is particularly preferably represented by the following general formula (IV):

Zr(OR₃)ₚ₁(R₄COCHCOR₅)ₚ₂ (IV),

the general formula (V):

Ti(OR₃)_{q1}(R₄COCHCOR₅)_{q2} (V), or

the general formula (VI):

Al(OR₃)ᵣ₁(R₄COCHCOR₅)ᵣ₂ (VI).

R₃ and R₄in the metal chelate compound may be the same or different alkyl groups having 1 to 6 carbon atoms, and their specific examples include an ethyl group, a n-propyl group, an i-propyl group, a n-butyl group, a sec-butyl group, a t-butyl group, a n-pentyl group, a phenyl group, etc. R₅ is the same alkyl group having 1 to 6 carbon atoms as above, or an alkoxy group having 1 to 16 carbon atoms such as a methoxy group, an ethoxy group, a n-propoxy group, an i-propoxy group, a n-butoxy group, a sec-butoxy group, a t-butoxy group, a lauryl group, and a stearyl group. Each of p₁, p₂, q₁, q₂, r₁ and r₂ in the general formulae (IV), (V) and (VI) is an integer selected such that the metal chelate compound is a 4 or 6-dentate coordination complex.

Specific examples of the metal chelate compounds include zirconium chelate compounds such as tri-n-butoxy mono(ethyl acetoacetato)zirconium, di-n-butoxy bis(ethyl acetoacetato)zirconium, n-butoxy tris(ethyl acetoacetato)zirconium, tetrakis(n-propylacetoacetato)zirconium, tetrakis(acetylacetoacetato)zirconium, and tetrakis(ethyl acetoacetato)zirconium; titanium chelate compounds such as diisopropoxy bis(ethyl acetoacetato)titanium, diisopropoxy bis(acetyl acetato)titanium, and diisopropoxy bis(acetyl acetone)titanium; and aluminum chelate compounds such as diisopropoxy mono(ethyl acetoacetato)aluminum, diisopropoxy mono(acetylacetonate)aluminum, isopropoxy bis(ethyl acetoacetato)aluminum, isopropoxy bis(acetylacetonato)aluminum, tris(ethyl acetoacetato)aluminum, tris(acetylacetonato)aluminum, and mono(acetylacetonato) bis(ethyl acetoacetato)aluminum. Preferred among the metal chelate compounds are tri-n-butoxy mono(ethyl acetoacetato)zirconium, diisopropoxy bis(acetylacetonato)titanium, diisopropoxy mono(ethyl acetoacetato)aluminum, and tris(ethyl acetoacetato)aluminum. These metal chelate compounds may be used alone or in combination. The metal chelate compounds may be partially hydrolyzed.

The organic metal compound used as the catalyst for the sol-gel reaction is not particularly restricted. The organic metal compound is preferably a highly active, organic transition metal compound, more preferably a tin compound having appropriate stability and activity. Specific examples of such tin compounds include carboxylic acid-based tin compounds such as (C₄H₉)₂Sn(OCOC₁₁H₂₃)₂, (C₄H₉)₂Sn(OCOCH═CHCOOC₄H₉)₂, (C₈H₁₇)₂Sn(OCOC₁₁H₂₃)₂, (C₈H₁₇)₂Sn(OCOCH═CHCOOC₄H₉)₂, and Sn(OCOCC₈H₁₇)₂; and ester-based tin compounds such as (C₄H₉)₂Sn(SCH₂COOC₈H₁₇)₂, (C₄H₉)₂Sn(SCH₂COOC₈H₁₇)₂, (C₈H₁₇)₂Sn(SCH₂CH₂COOC₈H₁₇)₂, and (C₈H₁₇)₂Sn(SCH₂COOC₁₂H₂₅)₂.

The shapes and sizes of the microcracks and domains surrounded by the microcracks can be controlled by selecting the amount of each agent, the timing of adding each agent, the reaction conditions (temperature, dilution ratio, etc.), the drying conditions (temperature, air quantity, etc.), the film thickness, etc.

(1-2) Application of Fine Particles

The thin film may be a fine-particle film formed by coating fine particles. The fine-particle film may be formed by applying a dispersion containing fine particles and a solvent, and drying the applied dispersion. Examples of materials for the fine particles include metal oxides such as Al₂O₃, TiO₂, ZnO, CeO₂, Y₂O₃, SiO₂, SnO₂, ZrO₂, Fe₂O₃, MgO, CuO, Mn₃O₄, ITO (Indium Tin Oxide) and ATO (Antimony Tin Oxide); polymers such as acrylics, polystyrenes, polymethyl methacrylate, polyethylene, and polystyrene-butadiene; semiconductors such as CdS, CdSe, and ZnS; metals such as Au and Ag; and composites thereof. In a case where the thin film is not removed before or after the completion of the electromagnetic shield, materials for the fine particles are selected depending on the desired light transmittance of the thin film. The fine particles are preferably as small as 1 nm to 100 μm. The ratio of the fine particles in the dispersion is preferably 0.1 to 70% by mass. The solvents used in the dispersion are preferably volatile and may be alcohols such as ethyl alcohol, amides such as dimethylformamide, other organic solvents such as sulfoxides, water, etc.

After evaporating the solvent, the fine-particle film is preferably subjected to a heat treatment, which increases the adhesion of the fine-particle film to the substrate and between the fine particles in the domains, so that the conductive material enters into microcracks only. The heating temperature may be selected depending on the fine particles. In the case of using fine polymer particles, the heat treatment is preferably carried out at the glass transition temperature Tg of the polymer or higher.

(1-3) Vapor Growth Method

The thin film may be formed by a vapor growth method. In the vapor growth method, microcracks are not generated by film shrinkage in drying process because the vapor deposition film contains no solvent, unlike those obtained by the sol-gel method and the fine particles application method. In the vapor growth method, a thin-film-forming material is vaporized and deposited onto the substrate, and crystal growth occurs in the resultant thin film. Accordingly, stress is accumulated in the growing film, resulting in the generation of microcracks. The degree of cracking due to the accumulated stress can be controlled by selecting the conditions such as the substrate temperature, the material and thickness of the thin film, and adhesion between the thin film and the substrate. Materials for the vapor deposition film may be metal oxides, metal nitrides, metal fluorides, etc., and their specific examples include MgO, SiO, SiO₂, Al₂O₃, GeO, NiO, CaO, BaO, Fe₂O₃, Y₂O₃, TiO₂, silicon nitride, MgF₂, LiF, AlF₃, CaF₂, etc. The vapor growth method may utilize a vacuum deposition method, a sputtering method, an activated sputtering method, a molecular beam epitaxy method, a cluster ion beam method, an ion-plating method, a plasma polymerization method, a plasma CVD method, a laser CVD method, a thermal CVD method, etc.

(1-4) Underlayer

The substrate having an electromagnetic-shielding layer preferably comprises an underlayer as an intermediate layer between the thin film and the substrate. The underlayer can control the surface conditions of the substrate, to improve the adhesion of the thin film and thus easily form the electromagnetic shield by plating. The electromagnetic-shielding layer may be formed by plating or bonding conductive particles as described hereinafter, and the underlayer is appropriately selected depending on the methods.

(a) Plated Underlayer

In the formation of the electromagnetic-shielding layer by plating, it is effective to form a plated underlayer. The plated underlayer comprises a resin as a binder and other components, if necessary. In a case where the conductive material is deposited by electroless plating, for instance, a plating catalyst, or its precursor that can be activated by an activation treatment, is effectively added to the binder before plating the electromagnetic-shielding layer. The plated underlayer may be subjected to a surface-activating treatment. The surface-activating treatment is preferably surface working for making the plated underlayer activatable by a chemical or physical activation treatment. An electroless plating layer can be formed only on portions of the plated underlayer exposed to the microcracks. In the case of forming an electromagnetic-shielding layer by electroplating, the plated underlayer preferably has conductivity. Because current flows through a conductive underlayer, the electromagnetic-shielding layer can be formed by electroplating only on portions of the plated underlayer exposed to the microcracks.

The plated underlayer may be patterned. Though not particularly restrictive, the patterning method is preferably a wet method such as a photolithography method, an ink-jet method, a printing method, and a transferring method. The plated underlayer preferably has a pattern corresponding to that of the electromagnetic-shielding layer.

Examples of binders for the plated underlayer include polymer binders such as polyvinyl chlorides, polycarbonates, polystyrenes, polymethyl methacrylate, polybutyl methacrylate, polyesters, polysulfones, polyphenylene oxide, polybutadiene, hydrocarbon resins, ketone resins, phenoxy resins, polyamides, polyvinyl acetate, ABS resins, polyurethanes, melamine resins, unsaturated polyesters, alkyd resins, epoxy resins, silicone resins, polyvinyl butyral, polyvinyl acetal, polyvinyl alcohol, polyvinyl pyrrolidone, and polyacrylamide; proteins such as gelatins and derivatives thereof; cellulose derivatives such as ethyl cellulose; and natural compounds such as starch, gum arabic, dextran, and pullulan.

There are no particular restrictions in the catalyst used for the plated underlayer and the method of adding the catalyst. For example, the catalyst may be adsorbed to the plated underlayer by soaking the underlayer in a Pd catalyst solution as in a usual electroless plating method, and the catalyst of reducing metal particles may be added to the plated underlayer. Reducing metal particles are preferably added to the plated underlayer. The reducing metal particles are not restricted with respect to the types of metals and particle size, as long as they are colloidal particles having plating catalytic activity and uniformly dispersed in the thin film. The reducing metal particles are preferably colloidal particles of a metal in Group VIII of the Periodic Table (Ni, Co, Rh, Pd, etc.), more preferably reducing colloidal Pd particles.

Methods for adding the reducing metal particles to the plated underlayer may be (1) a method of adding a colloidal dispersion of the reducing metal particles to the plated underlayer; (2) a method of adding a precursor of the reducing metal particles to the plated underlayer, and precipitating the reducing metal particles; (3) a method of adding fine silver particles to the plated underlayer, and bringing them into contact with Pd ions in an activation treatment to precipitate Pd in the plated underlayer, like Omnishield SST Process available from Shipley Far East Ltd.; etc.

In a case where the conductive material is electroplated onto the plated underlayer by supplying current to the plated underlayer, the plated underlayer is preferably semiconductive. The term “semiconductive plated underlayer” used herein means a plated underlayer having a sheet resistance of 10¹⁰ Ω/square or less. The semiconductive plated underlayer may be formed by adding a low- or high-molecular-weight antistatic agent, a conductive polymer, a metal filler, carbon, etc. to the plated underlayer, or by using a semiconductive metal or metal oxide.

The plated underlayer may be treated to activate the plating catalyst or to increase the adhesion of the plated underlayer to an overlying thin film. The activation treatment may be a chemical treatment such as an acid treatment and an alkali treatment, or a physical treatment such as UV irradiation, an oxygen plasma treatment, a hydrogen plasma treatment and a corona treatment.

(b) Bondable Underlayer

In a case where the electromagnetic-shielding layer is formed by a conductive particle-bonding method, it is effective to use as the underlayer a bondable underlayer having bondability to conductive particles. The bondable underlayer comprises a resin binder as an essential component. For example, the bondable underlayer is preferably obtained by using a binder having bondability to conductive particles; by adding a substance (inorganic or organic particles) having bondability to conductive particles to the binder; by subjecting the binder layer to a surface-activating treatment such as a chemical treatment and a physical treatment with light or heat energy; or by their combination.

The binder for the bondable underlayer may be the same as for the plated underlayer. In addition, the binder for the bondable underlayer may be made of known curing resins such as heat-curing resins and active energy ray-curable resins. The heat-curing resins may utilize the crosslinking of prepolymers such as melamine resins, urethane resins and epoxy resins. The active energy ray-curable resins may comprise polyfunctional monomers, and their examples include active energy ray-curable compounds such as a polyfunctional (meth)acrylates such as pentaerythritol tetra(meth)acrylate, dipentaerythritol hexa(meth)acrylate, trimethylolpropane tri(meth)acrylate, etc. The active energy ray may be ultraviolet ray, electron ray, gamma ray, etc., preferably ultraviolet ray. In a case where the active energy ray-curable resin is hardened by ultraviolet ray irradiation, a polymerization initiator is preferably added to the curable compound, if necessary.

In the case of adding the substance having bondability to conductive particles to the binder, the bondable substance is preferably a functional silane coupling agent (functional silane compound). The bondable underlayer can be formed by applying the functional silane coupling agent to the binder layer. The binder coated with the silane coupling agent has bondability to the conductive particles because of its functional group. The bondable underlayer may be formed by applying the silane coupling agent directly to the substrate, to increase adhesion between the bondable underlayer and the substrate.

The functional silane coupling agent is a compound having a silicon atom connected to at organic group having a functional group (simply called “organic functional group”), a hydrolyzable group or a hydroxyl group. The functional group may be a mercapto group, a primary amino group, a secondary amino group, a (meth)acryloyloxy group, an epoxy group, a vinyl group, a carboxy group, a chlorine group, an isocyanate group, etc. The organic functional group is not hydrolyzable because it is connected to a silicon atom at the position of a carbon atom. The silicon atom may be bonded to an organic group having no functional group, which is preferably a lower alkyl group having 4 or less carbon atoms such as a methyl group or a phenyl group.

In the organic functional group, a moiety other than a functional group (a moiety between the functional group and the silicon atom) is preferably a divalent organic group such as an alkylene group, a phenylene group, a cycloalkylene group, and a combination thereof. In the divalent organic group, carbon atoms other than terminal carbon atoms may be substituted by an ether oxygen atom. The divalent organic group is preferably an alkylene group, more preferably an alkylene group having 2 to 8 carbon atoms, most preferably a trimethylene group.

The functional group may be bonded to the end of the divalent organic group directly or via a polyvalent group or an atom other than carbon. For example, the functional group may be connected to the divalent organic group via a bond such as an ester bond, an ether bond and an amide bond. Though not particularly restrictive, examples of the organic functional groups include a mercaptopropylene group, a vinyl group, a 3-(4-vinylphenyl)propyl group, a 3-(meth)acryloylpropyl group, a 3-glycidoxypropyl group, a 2-(3,4-epoxycyclohexyl)ethyl group, a 3-aminopropyl group, an N-(2-aminoethyl)-3-aminopropyl group, an N-allyl-3-aminopropyl group, an N-phenyl-3-aminopropyl group, a 3-chloropropyl group, a 3-isocyanatepropyl group, etc.

The hydrolyzable group bonded to the silicon atom can react with water to produce a silanol group. The hydrolyzable group may be a residue obtained by removing a hydrogen atom from a hydroxyl group of a hydroxyl-containing compound (e.g. an alkoxy group), an acyl group, an amino group, a halogen atom, an acetoxy group, etc. The hydrolyzable group is preferably an alkoxy group or a halogen atom, more preferably an alkoxy group having 4 or less carbon atoms, or a chlorine or bromine atom, most preferably an alkoxy group having 4 or less carbon atoms. Though the functional silane compounds generally contain one silicon atom, they may be compounds containing 2 or more silicon atoms such as disiloxane derivatives and disilane derivatives. The functional silane compound preferably contains a silicon atom connected to four substituents, which may be an organic group having a mercapto group, a hydrolyzable group, and two substituents selected from organic groups having no functional groups and hydrolyzable groups. When the functional silane compound contains a mercapto group, the underlayer shows high conductivity and excellent bondability to a noble metal.

The functional silane compound containing a mercapto group (a mercaptosilane compound) is preferably represented by the following general formula (VII):

HS—R₇—SiXₙ(R₈)₃₋ₙ (VII),

wherein R₇ is a divalent hydrocarbon group, R₈ is a monovalent hydrocarbon group, X is a hydroxyl group or a hydrolyzable functional group, and n is an integer of 1 to 3.

R₇ in the general formula (VII) is preferably an alkylene group having 2 to 6 carbon atoms, more preferably a propylene group. R₈ is preferably an alkyl group having 4 or less carbon atoms, more preferably a methyl group or an ethyl group. X is preferably a hydrolyzable functional group, more preferably an alkoxy group having 4 or less carbon atoms, most preferably a methoxy group or an ethoxy group. n is preferably an integer of 2 or 3.

Examples of the mercaptosilane compounds represented by the general formula (VII) include HS—CH₂CH₂CH₂—Si(OMe)₃, HS—CH₂CH₂CH₂—Si(OEt)₃, HS—CH₂CH₂CH₂—Si(OPr)₃, HS—CH₂CH₂CH₂—SiMe(OMe)₂, HS—CH₂CH₂CH₂—SiMe(OEt)₂, HS—CH₂CH₂CH₂—SiMe(OPr)₂, HS—CH₂CH₂CH₂—SiMe₂(OMe), HS—CH₂CH₂CH₂—SiMe₂(OEt), HS—CH₂CH₂CH₂—SiMe₂(OPr), HS—CH₂CH₂CH₂—SiCl₃, HS—CH₂CH₂CH₂—SiBr₃, HS—CH₂CH₂CH₂—SiMeCl₂, HS—CH₂CH₂CH₂—SiMeBr₂, HS—CH₂CH₂CH₂—SiMe₂Cl, HS—CH₂CH₂CH₂—SiMe₂Br, etc. In the above formulae, Me represents a methyl group, Et represents an ethyl group, and Pr represents a n-propyl group.

The bondable underlayer may be patterned similarly to the plated underlayer as described in (a) above.

(2) Formation of Electromagnetic-Shielding Layer

Though not particularly restrictive, the conductive materials for the electromagnetic-shielding layer in the image display of the present invention may be metals, metal oxides, conjugated polymers, and composites thereof. In a case where the electromagnetic-shielding layer should have a relatively high conductivity, the conductive material is preferably a metal oxide such as ITO, or at least one metal selected from the group consisting of copper, aluminum, nickel, iron, gold, silver, stainless steel, tungsten, chromium and titanium The conductive material may be a material for the transparent conductive layer described hereinafter. The conductive material may be deposited or adhered to form the electromagnetic-shielding layer by a plating method or the conductive particles bonding method described below.

(2-1) Plating Method

Unlimited examples of the plating method are electroless plating, electroplating, hot dipping, vacuum plating such as vacuum deposition and ion plating, etc. The details of the plating methods are described in Plating Technology Handbook, 1971, Tokyo Plating Material Association, Technology Committee, etc.

At least one conductive metal selected from the group consisting of copper, aluminum, nickel, iron, gold, silver, stainless steel, tungsten, chromium and titanium is preferably used to form the electromagnetic-shielding layer by plating. A plurality of plating steps may be conducted with different metals to form a laminated electromagnetic-shielding layer with improved stability. The laminated layer may be a known combination of metals, and its example may be a combination of electroless-plated nickel and electroless-plated gold. Further, electroplating and electroless plating may be combined to form a laminated electromagnetic-shielding layer of one metal or a laminated electromagnetic-shielding layer of two or more metals.

The formation of a substrate having an electromagnetic-shielding layer by a plating method and a direct or indirect method is exemplified below with reference to drawings.

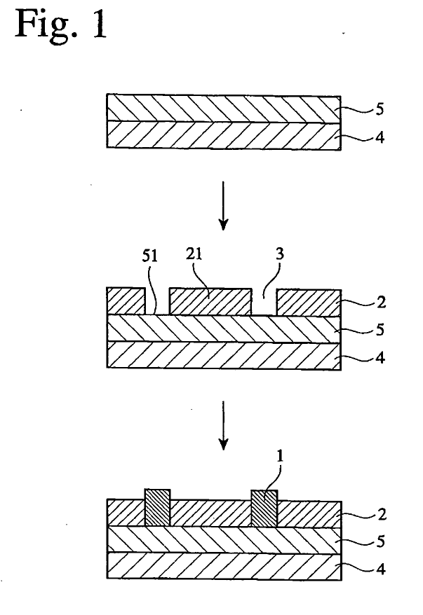

In the direct method, as shown in FIG. 1, an underlayer 5 is plated on a substrate 4, and a thin film 2 is formed on the plated underlayer 5. Microcracks 3 are generated in a network manner in the thin film 2, and a conductive material 1 is deposited by plating on portions 51 of the plated underlayer 5 exposed in the microcracks 3. The thin film 2 has domains 21. In the direct method, the plating catalyst or its precursor is preferably added to the plated underlayer 5. The plating catalyst precursor can be converted to an active catalyst by an activation treatment of the exposed portions 51 before the deposition of the conductive material 1.

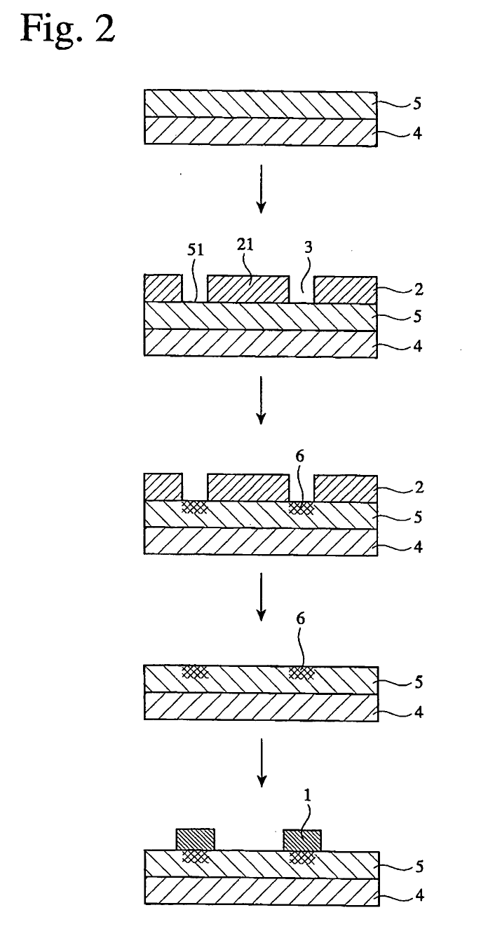

In the indirect method, as shown in FIG. 2, an underlayer 5 is plated on a substrate 4, and a thin film 2 is formed on the plated underlayer 5. Microcracks 3 are generated in a network manner in the thin film 2, and portions 51 of the plated underlayer 5 exposed to the microcracks 3 are subjected to an activation treatment. The thin film 2 is then removed, and a conductive material 1 is deposited on the activated portions 6 by plating. The catalyst precursor that can be converted to an active catalyst by an activation treatment is preferably added to the plated underlayer 5. Further, the plated underlayer 5 is preferably subjected to surface working so that that it can be activated by the activation treatment. The activation treatment may be a chemical treatment such as an acid treatment and an alkali treatment, or a physical treatment such as UV irradiation, an oxygen plasma treatment, a hydrogen plasma treatment, and a corona treatment.

The thickness of the electromagnetic-shielding layer formed by the plating method may be controlled by changing a plating bath composition and/or plating conditions such as temperature and time. The thickness of the electromagnetic-shielding layer is preferably 0.01 to 10 μm.

In the case of using two or more conductive materials, the direct method and the indirect method are effectively combined. For example, a first electromagnetic-shielding layer may be formed by the direct method, and a second electromagnetic-shielding layer may then be formed by the indirect method after the thin film is removed. The direct method and the indirect method may be selected depending on the use of the electromagnetic-shielding layer, etc. The direct method is preferable to control line width in the electromagnetic-shielding layer, and the indirect method is preferable in surface uniformity and an electromagnetic shield density.

The substrate having an electromagnetic-shielding layer formed thereon may be laminated with another material layer. The thin film may be removed from the electromagnetic shield formed by the direct method.

As described above, the patterning of the plated underlayer makes it possible to deposit a conductive material in a predetermined pattern. After forming the electromagnetic-shielding layer, patterning may be conducted by a chemical etching method using photolithography, etc. or by a physical etching method using laser beams, etc.

(2-2) Bonding of Conductive Particles

The conductive particles may be made of one conductive material, a plurality of conductive materials, or a combination of a conductive material and an insulating or semiconductive material. Such composite conductive particles may have various forms and compositions, and examples thereof include particles made of a mixture of different conductive materials such as an alloy; particles having a core-shell structure of different materials, such as insulating particles coated with a conductive metal; chain or spherical secondary particles formed by agglomeration of different primary particles; etc.

Conductive materials for the conductive particles may be generally selected from (i) materials having conductivity by free electrons in a metal bond; (ii) materials utilizing transfer of excess electrons for charge transfer; (iii) materials utilizing transfer of holes for charge transfer; (iv) organic polymers having conductivity by the interaction of n-bonds in a main chain; and (v) organic polymers utilizing interaction of groups in side chains for charge transfer. Specific examples of the materials (i) to (iii) include metals and alloys such as zinc, aluminum, antimony, iridium, indium, gold, silver, chromium, cobalt, constantan, zirconium, copper, tin, tungsten, tantalum, iron, lead, nichrome, nickel, platinum, rhodium, palladium, beryllium, magnesium, manganin, molybdenum, alumel, chromel and duralumin; metal oxides such as titanium oxide, tin oxide, iron oxide, antimony oxide, indium oxide, zirconium oxide, copper oxide, tungsten oxide, lead oxide, and bismuth oxide; carbonized tungsten such as tungsten carbide; and carbon black. Examples of the organic conductive polymers (iv) and (v) include polyacetylene-based polymers, polyphenylene-based polymers, heterocycle-based polymers, and aromatic amine-based polymers. Specific examples of the polyacetylene-based polymers include polyacetylene and polyphenylacetylene, specific examples of the polyphenylene-based polymers include polyparaphenylene, polyphenylenevinylene, and thiophenylene-based polymers, specific examples of the heterocycle-based polymers include polypyrrole and polythiophene, and specific examples of the aromatic amine-based polymers include polyaniline and polydiaminoanthraquinone. The conductive particles preferably comprise at least one material selected form the group consisting of gold, silver, copper, and aluminum.

Examples of the insulating materials and the semiconductors usable for the composite conductive particles include oxides such as Al₂O₃ and SiO₂; polymers such as polyvinyl chlorides, polycarbonates, polystyrenes, polymethyl methacrylate, polybutyl methacrylate, polyesters, polysulfones, polyphenylene oxides, polybutadienes, hydrocarbon resins, ketone resins, phenoxy resins, polyamides, ethyl cellulose, polyvinyl acetate, ABS resins, polyurethanes, melamine resins, unsaturated polyesters, alkyd resins, epoxy resins, silicone resins, and polyvinyl butyral; semiconductors such as CdS, CdSe, and ZnS; etc.

The average particle size of the conductive particles is preferably 0.001 to 100 μm, more preferably 0.005 to 10 μm. The conductive particles may be produced by known methods. For example, colloidal noble metal particles of gold, silver, etc. can be produced by a reductive reaction from a solution of a noble metal salt. The methods for producing fine particles of metals, alloys or metal oxides are described in detail in Akio Kato and Hiromichi Arai, Modern Applied Chemistry Series 4, Ultra-Fine Particles, Chemistry and Functions, Asakura Shoten (1993), etc.

The conductive particles are bonded to a surface of the bondable underlayer. The bondable underlayer may comprise a material having bondability to the predetermined conductive particles, or may be a layer provided with bondability to the conductive particles by subjecting the binder layer to a surface-activating treatment. The bondability of the bondable underlayer is the ability of forming an ionic bond, a covalent bond, a hydrogen bond, or a van der Waals bond with the conductive particles. The higher bondability of the underlayer makes it possible to fill the microcracks with the conductive particles at a higher speed. The conductive particles may be surface-modified, if necessary.

In the case of using conductive particles of a noble metal such as gold and silver, thiol groups are effectively attached to the bondable underlayer by the method described in (1-4), (b). A functional group such as a carboxyl group may be fixed to the bondable underlayer, and the noble metal particles may be surface-modified with an alkanethiol having an amine group. Positive- or negative-charged conductive particles may be used with an anionic or cationic underlayer. In this method, bondability between the conductive particles and the bondable underlayer is higher than between the conductive particles and the domains. Thus, the conductive particles are selectively attached to the portions in the microcracks, thereby increasing the light transmittance of the electromagnetic-shielding layer.

The conductive particles may be attached to the bondable underlayer by a solution method or a gas phase method. It should be noted that the term “attaching” used herein has a wide meaning including bonding, adhering, and depositing. The solution method is preferable when the conductive particles are attached to the thin film-carrying substrate in a relatively large area. In the solution method, the substrate with the thin film may be soaked in a solution containing the conductive particles. The soaking temperature and time, the concentration of the solution, a solvent, etc. may be selected depending on bondability between the conductive particles and the bondable underlayer. After soaking, the substrate is preferably dried at room temperature and then burned. The burning temperature may be controlled depending on the materials of the conductive particles and the substrate. For example, gold particles may be attached to the bondable underlayer, by soaking a glass substrate with a thin film in a solution containing colloidal gold particles at room temperature overnight, drying it at room temperature, and burning it at 300° C. for 1 hour.

The gas phase method for attaching conductive particles may be a vacuum deposition method, a sputtering method, an activated sputtering method, a molecular beam epitaxy method, a cluster ion beam method, an ion-plating method, a plasma polymerization method, a plasma CVD method, a laser CVD method, a thermal CVD method, etc.

In both of the solution method and the gas phase method, the conductive particles are preferably subjected to a surface treatment to improve their stability. In the surface treatment, the conductive particles may be treated with a nonionic surfactant, a cationic surfactant, an anionic surfactant, a silicon coupling agent, an aluminum coupling agent, etc.

The conductive particle-attaching method may be used in the direct or indirect method as well as in the plating method. The direct or indirect method using the conductive particle-attaching method is essentially the same as those using the plating method. In the direct method, a substance having bondability to conductive particles is preferably added in advance to the bondable underlayer, which comprises a binder having bondability to conductive particles, or is provided with increased bondability by an activation treatment such as a chemical treatment and a physical treatment. In the indirect method, the exposed portions of the bondable underlayer are preferably activated by a bondability-enhancing treatment such as a chemical treatment and a physical treatment. The chemical treatment may be such that a compound such as a functional silane coupling agent is bonded to the portions of the binder layer exposed to the microcracks. In this case, the underlayer preferably comprises a binder having high affinity for a compound having a functional group.

### [3] Functional Layers of Electromagnetic Shield

The electromagnetic shield of the present invention may have at least one functional layer, if necessary, though it may be composed of only the substrate and the electromagnetic-shielding layer formed thereon. One functional layer may have a plurality of functions. Examples of the functional layers include a near infrared ray-shielding layer, a reflection-preventing layer, an anti-staining layer, a hard coat, an adhesive layer, a hot-melt layer, a protective film layer, etc.

(1) Hard Coat

A scratch-preventing hard coat may comprise usual hardening resins. The hardening resins may be thermosetting resins, active energy ray-curable resins, etc. Examples of the thermosetting resins include resins utilizing a crosslinking reaction of prepolymers, such as melamine resins, urethane resins, and epoxy resins. The active energy ray-curable resins may comprise polyfunctional monomers such as polyfunctional acrylates or methacrylates. The active energy ray may be ultraviolet ray, electron ray, gamma ray, etc., preferably ultraviolet ray. In the case of ultraviolet ray irradiation, a polymerization initiator is preferably added to the resin, if necessary. Examples of the active energy ray-curable resins include pentaerythritol tetra(meth)acrylate and dipentaerythritol hexa(meth)acrylate.

Fine or colloidal particles of a metal oxide such as silica, alumina, zirconia and titania may be added as a filler to the hard coat to increase its hardness. Harder particles are preferably added, and they preferably have a Mohs' hardness of 6 or more. The fine particles preferably have diameters of 1 to 100 nm. When their diameters are more than 100 nm, the fine particles make the hard coat hazy. When their diameters are less than 1 nm, it is difficult to disperse the fine particles. The ratio of the fine particles to the hardening resin is preferably 5 to 50% by volume, more preferably 20 to 45% by volume. When the ratio is more than 50% by volume, the thin film is brittle. When the ratio is less than 5% by volume, the hardness cannot be sufficiently increased. The fine metal oxide particles are preferably surface-modified to increase dispersibility and interaction with the resin. In the surface modification, the particles may be treated with a silane coupling agent having a (meth)acryl group, a (meth)acrylic acid derivative having a polar group such as a carboxylic acid group and a phosphoric acid group, etc.

The thickness of the hard coat is preferably 2 to 30 μm, more preferably 4 to 10 μm. The hydrophilicity and/or adhesion of the hard coat may be increased by adding an anion surfactant or a cation surfactant, or by a surface treatment such as a corona treatment and a glow treatment.

(2) Reflection-Preventing Layer

The reflection-preventing layer may be formed by laminating a high-refractive-index material and a low-refractive-index material alternately. The reflection-preventing layer of a multilayer structure has an excellent effect of preventing surface reflection. The reflection-preventing layer of a multilayer structure is specifically produced by forming a layer of a low-refractive-index material such as SiO₂ and a layer of a high-refractive-index material such as TiO₂ and ZrO₂ alternately by a vapor growth method such as vapor deposition, a sol-gel method, etc. The refractive index of the low-refractive-index layer is preferably 1.45 or less to increase the reflection-preventing effect. The refractive index of the high-refractive-index layer may be increased by using a high-refractive-index binder resin, and/or by adding high-refractive-index, ultrafine particles to a binder resin. The refractive index of the high-refractive-index layer is preferably 1.55 to 2.70. Resins for the high-refractive-index layer may be any transparent resins such as thermosetting resins, thermoplastic resins, and radiation-curing resins including ultraviolet-curing resins. Examples of the thermosetting resins include phenol resins, melamine resins, polyurethane resins, urea resins, diallyl phthalate resins, guanamine resins, unsaturated polyester resins, aminoalkyd resins, melamine-urea cocondensation resins, silicone resins, polysiloxane resins, etc. Hardening agents such as crosslinking agents and polymerization initiators, polymerization accelerators, solvents, viscosity-controlling agents, etc. may be added to the resins, if necessary.

ZnO (refractive index n=1.9), TiO₂ (n=2.3 to 2.7), CeO₂ (n=1.95), SnO₂ (n=1.95), ITO (n=1.95), etc. may be used for the high-refractive-index, ultrafine particles. The reflection-preventing layer has an ultraviolet-shielding effect in addition to a reflection-preventing effect, when fine particles of ZnO, TiO₂, or CeO₂ are used. Further, in the case of using fine particles of SnO₂ or ITO doped with antimony, the reflection-preventing layer has an antistatic effect to prevent the attachment of dust. Further examples of the materials for the ultrafine particles include Al₂O₃ (n=1.63), La₂O₃ (n=1.95), ZrO₂ (n=2.05), Y₂O₃ (n=1.87), etc. The materials may be used alone or in combination. The ultrafine particles are preferably colloidal when dispersed in an organic solvent or water. The particle size of the ultrafine particles is preferably 1 to 100 nm, more preferably 5 to 20 nm, from the viewpoint of the transparency of the thin film.

A surface of the electromagnetic shield, such as the hard coat, may be directly subjected to a roughening treatment. The surface-roughening treatment may be sandblasting, embossment, etc. Further, a roughened or porous surface having a sea-island structure may be provided to the uppermost layer. The rough surface may be provided by adding an inorganic filler such as silica or an organic filler such as resin particles to the uppermost resin layer during hardening the resin layer by radiation and/or heat.

(3) Near Infrared Ray-Shielding Layer

Examples of materials for absorbing near-infrared rays include metal sulfides and thiourea compounds; phthalocyanine; metal complexes; copper compounds and bisthiourea compounds; phosphorus compounds, copper compounds; metal oxides such as indium oxide, tin oxide, titanium dioxide, cerium oxide, zirconium oxide, zinc oxide, tantalum oxide, niobium oxide, and zinc sulfide; etc.

(4) Anti-Staining Layer

The anti-staining layer has a critical surface tension of 20 dyn/cm or less to show anti-staining property. When the critical surface tension of the anti-staining layer is more than 20 dyn/cm, it is difficult to remove stain from the layer surface. Materials for the anti-staining layer are preferably radiation-curing resins, particularly fluorine-containing materials from the viewpoint of anti-staining property.

Examples of the fluorine-containing materials include vinylidene fluoride copolymers, fluoroolefin-hydrocarbon olefin copolymers, fluorine-containing epoxy resins, fluorine-containing epoxy acrylates, fluorine-containing silicones, fluorine-containing alkoxysilanes, etc., which can be dissolved in an organic solvent and easily handled. These fluorine-containing materials may be used alone or in combination.

(5) Protective Film

The protective film may be a known transparent film. Specifically, the protective film may be made of resins such as polyethylene terephthalate (PET), triacetyl cellulose (TAC), polyarylates, polyethers, polycarbonates (PC), polysulfones, polyethersulfones, cellophanes, aromatic polyamides, polyvinyl alcohol, polyethylene (PE), polypropylene (PP), polyvinyl chloride (PVC), polystyrene (PS), acrylonitrile-butadiene-styrene copolymers (ABS), polymethyl methacrylate (PMMA), polyamides, polyacetal (POM), polyphenylene terephthalate (PPE), polybutylene terephthalate (PBT), polyphenylene sulfide (PPS), polyamide-imides (PAI), polyetheramides (PEI), polyetheretherketones (PEEK), polyimides (PI), and polytetrafluoroethylene.

(6) Adhesive Layer

The adhesive layer may be made of usual resins. Specific examples of such resins include poly(meth)acrylate such as polyethyl acrylate, polybutyl acrylate, poly-2-ethylhexyl acrylate, poly-t-butyl acrylate, poly-3-ethoxypropyl acrylate, polyoxycarbonyl tetramethacrylate, polymethyl acrylate, polyisopropyl methacrylate, polydodecyl methacrylate, polytetradecyl methacrylate, poly-n-propyl methacrylate, poly-3,3,5-trimethylcyclohexyl methacrylate, polyethyl methacrylate, poly-2-nitro-2-methylpropyl methacrylate, polytetracarbanyl methacrylate, poly-1,1-diethylpropyl methacrylate, and polymethyl methacrylate, etc.

(7) Hot-Melt Resin Layer

Hot-melt resins easy to handle and use are preferably used as adhesives for attaching the electromagnetic shield to a glass plate, etc. The hot-melt resin is preferably used in the form of a film, which may be produced from thermoplastic resins such as ethylene-vinyl acetate copolymers (EVA), modified EVAs, synthetic rubbers, polyurethanes, PE, PP, PVC, polyvinyl butyral (PVB), and ionomer resins. The hot-melt resin layer may be obtained by shaping the thermoplastic resin into a film (0.1 μm to 1 mm) by a usual method. Further, the hot-melt resin layer may be a film obtained by reacting and hardening a reactive hot-melt adhesive.

(8) Other Layers

The electromagnetic shield may further have known functional layers such as a layer of protecting the conductive material by preventing oxidation of the metal, etc., a dust-proof layer, an antistatic layer, an ultraviolet-shielding layer, and a layer for shielding gas such as steam.

The electromagnetic shield may be grounded to increase the electromagnetic-shielding properties. The conductive material may be directly grounded, or a surface layer having a low surface resistance and a high dielectric constant may be grounded.

### [4] Image Display

The image display of the present invention is not particularly restricted, as long as it has the above-described electromagnetic shield with an irregular network structure. Examples of the image displays include CRTs, PDPs, organic electroluminescence displays, and liquid-crystal displays. The image display of the present invention is preferably CRT or PDP having the electromagnetic shield. The electromagnetic shield with an irregular network structure has high transparency and excellent electromagnetic-shielding properties. Thus, even when the electromagnetic shield is formed on other articles than the image display, such as windows of office buildings, houses, automobiles, trains, etc., it can also exhibit an excellent electromagnetic-shielding effect without lowering light transmittance.

The present invention will be described in more detail below with reference to Examples without intention of restricting the scope of the present invention.

### EXAMPLE 1

### [1] Production of Substrate Having an Electromagnetic-Shielding Layer

(1-1) Formation of Plated Underlayer

Palladium chloride was reduced by sodium borohydride in a heptane/water dispersion to obtain a dispersion of metallic Pd particles having an average particle size of 5 nm. 5% by mass, based on the metallic Pd particles, of polymethyl methacrylate was added to the dispersion, and diluted with toluene to prepare a coating liquid. The coating liquid was applied to a corona-discharged polyethylene terephthalate substrate of 100 μm (thickness)×100 mm×100 mm by a spin coater to form a plated underlayer. The plated underlayer was subjected to an alkali edging treatment using a 2N aqueous sodium hydroxide solution at 70° C. for 1 hour.

(1-2) Formation of Sol-Gel Film

Water, hydrochloric acid and propyl alcohol were added to tetraethoxysilicate and stirred at room temperature for 30 minutes to hydrolyze tetraethoxysilicate. The resultant hydrolysate liquid was applied by a rod coater to the plated underlayer obtained in (1-1), and dried at 120° C. for 30 minutes to form a sol-gel film having a dry thickness of 0.4 μm. The observation of the sol-gel film surface by an optical microscope revealed that microcracks were formed in the sol-gel film, resulting in domains surrounded by the microcracks.

(1-3) Plating

An ultrathin nickel layer was deposited on the substrate having the plated underlayer and the sol-gel film by reducing nickel nitrate with a reducing agent of dimethylamine borane in ethanol. The substrate was then treated with an electroless copper plating liquid (OPC COPPER H, available from Okuno Chemical Industries Co., Ltd.) to deposit a copper layer having a thickness of 2 μm. An electroless-plated layer thus obtained had a sheet resistance of 0.8 Ω/square and light transmittance of 81% (measured by a spectrophotometer). The observation by an electron microscope revealed that the microcracks were filled with copper to form an electromagnetic-shielding layer.

### [2] Production of Electromagnetic Shield

(2-1) Preparation of Coating Liquid for Hard Coat

97 g of methanol, 163 g of i-propyl alcohol, and 163 g of butyl acetate were added to 116 g of a dispersion of 43% by mass of fine silica particles in methanol to prepare a mixture liquid. 200 g of a mixture of dipentaerythritol pentaacrylate and dipentaerythritol hexaacrylate (DPHA, available from Nippon Kayaku Co., Ltd.) was dissolved in the mixture liquid. 7.5 g of a photopolymerization initiator (IRGACURE 184, available from Chiba-Geigy Corporation) was then dissolved in the liquid. The resulting mixture was stirred for 30 minutes and filtered by a polypropylene filter having a pore diameter of 1 μm to prepare a coating liquid for a hard coat.

(2-2) Formation of Hard Coat

The coating liquid for a hard coat was applied to a rear surface of the substrate having an electromagnetic-shielding layer by a wire bar to a thickness of 8 μm. The applied liquid was dried and irradiated with ultraviolet rays to form a hard coat, thereby producing an electromagnetic shield.

The electromagnetic shield thus produced was attached to a glass surface of PDP by a hot-melt resin film HIRODINE 7573T (trade name) available from Yasuhara Chemical Co., Ltd., to produce an image display having an electromagnetic shield.

### Comparative Example 1

An image display having an electromagnetic shield was produced in the same manner as in Example 1 except for using a substrate with a lattice conductor in place of the substrate having an electromagnetic-shielding layer. Specifically, a copper foil having a thickness of 12 μm was laminated to a polyethylene terephthalate substrate of 100 μm (thickness)×100 mm×100 mm, and a surface of the copper foil was spin-coated with a photoresist. With the photoresist masked by a lattice mesh pattern having a line width of 20 μm and square pores of 200 μm each, the photoresist was irradiated with ultraviolet rays through the mask pores, and the exposed portions of the photoresist were printed onto the copper foil. After the mask was removed, the unexposed portions (unprinted portions) of the photoresist was removed by soaking the substrate in a photoresist-removing liquid (aqueous sodium carbonate solution), and a mesh pattern of the photoresist was developed on the copper foil. The substrate was soaked in an etching liquid containing iron chloride in hydrochloric acid, to etch portions of the copper foil corresponding to the undeveloped portions. The developed portions of the photoresist were removed by soaking the etched substrate in a photoresist-removing liquid (diluted sodium hydroxide solution) to obtain a substrate with a lattice conductor.

Evaluation of Image Display Having Electromagnetic Shield

The electromagnetic shield of the image display of Example 1 had an electromagnetic shielding of 52 dB and a light transmittance of 70%, while the electromagnetic shield of the image display of Comparative Example 1 had an electromagnetic shielding of 51 dB and a light transmittance of 62%. It is thus clear that the electromagnetic shield of Example 1 had higher light transmittance than that of the electromagnetic shield of Comparative Example 1, with substantially the same electromagnetic shielding.

Images shown in the image displays of Example 1 and Comparative Example 1 were observed. No defects were observed in image in the electromagnetic shield of the image display of Example 1, while the image display of Comparative Example 1 provided granular and nonuniform image because of the lattice conductor.

As described in detail above, the present invention provides an electromagnetic shield comprising a conductive material with an irregular network structure, by forming a thin film on a light transmittable substrate, generating microcracks in a network manner in the thin film, and filling the microcracks with the conductive material. Because the network structure of the electromagnetic shield is remarkably uniform and fine, the electromagnetic shield has excellent electromagnetic-shielding properties and high light transmittance, useful for image displays. Further, the method of the present invention utilizing naturally occurring microcracks can produce larger-area electromagnetic shields at a lower cost than the conventional photolithography methods.

What is claimed is:

1. An image display having an electromagnetic shield comprising a conductive material with an irregular network structure.

2. The image display of claim 1, wherein said network structure comprises thin lines having a width of 10 nm to 10 μm.

3. A method for producing an image display having an electromagnetic shield, comprising the steps of forming a thin film on a substrate; generating microcracks in a network manner in said thin film; and filling said microcracks with a conductive material to form said electromagnetic shield.

4. A method for producing an image display having an electromagnetic shield, comprising the steps of forming an underlayer on a substrate; forming a thin film on said underlayer; generating microcracks in a network manner in said thin film; activating portions of said underlayer exposed to said microcracks; removing said thin film; and depositing or bonding a conductive material only onto the activated portions of said underlayer to form said electromagnetic shield.

5. The method of claim 3, wherein said thin film is (1) a sol-gel film obtained by applying a sol-gel liquid, (2) a fine-particle film obtained by applying a liquid containing fine particles, or (3) a vapor deposition film obtained by depositing a vaporized thin-film-forming material; and wherein said microcracks are generated by drying said sol-gel film or said fine-particle film, or by accumulating stress in said vapor deposition film during its growth.

6. The method of claim 4, wherein said thin film is (1) a sol-gel film obtained by applying a sol-gel liquid, (2) a fine-particle film obtained by applying a liquid containing fine particles, or (3) a vapor deposition film obtained by depositing a vaporized thin-film-forming material; and wherein said microcracks are generated by drying said sol-gel film or said fine-particle film or by accumulating stress in said vapor deposition film during its growth.

7. The method of claim 3, comprising the steps of forming said thin film after forming an underlayer by plating on said substrate; generating microcracks in a network manner in said thin film; and depositing said conductive material on portions of said plated underlayer exposed to said microcracks by plating to form said electromagnetic shield.

8. The method of claim 4, comprising the steps of forming said thin film after forming an underlayer by plating on said substrate; generating microcracks in a network manner in said thin film; activating portions of said plated underlayer exposed to said microcracks, and depositing said conductive material to the activated portions of said plated underlayer by plating to form said electromagnetic shield.

9. The method of claim 7, wherein said plating is electroless plating; and wherein said plated underlayer comprises a plating catalyst or its precursor.

10. The method of claim 8, wherein said plating is electroless plating; and wherein said plated underlayer comprises a plating catalyst or its precursor.

11. The method of claim 3, comprising the steps of forming said thin film after forming a bondable underlayer having bondability to said conductive material or acquiring bondability to said conductive material by activation on said substrate; generating microcracks in a network manner in said thin film; and bonding particles of said conductive material to portions of said bondable underlayer exposed to said microcracks.

12. The method of claim 4, comprising the steps of forming said thin film after forming a bondable underlayer having bondability to said conductive material or acquiring bondability to said conductive material by activation on said substrate; generating microcracks in a network manner in said thin film; activating portions of said bondable underlayer exposed to said microcracks; and bonding particles of said conductive material to the activated portions of said bondable underlayer.

13. The method of claim 1l, wherein said bondable underlayer has a functional group bondable to said conductive material or a functional group acquiring bondability to said conductive material by activation.

14. The method of claim 12, wherein said bondable underlayer has a functional group bondable to said conductive material or a functional group acquiring bondability to said conductive material by activation.
